(19) United States
(12) Patent Application Publication
(10) Pub. No.: US 2025/0372400 A1
(43) Pub. Date: Dec. 4, 2025

(54) FABRICATING METHOD OF PACKAGE SUBSTRATE

(71) Applicant: AaltoSemi Inc., Nanjing City (CN)

(72) Inventors: Sung-Kun LIN, Nanjing City (CN); Yin-Ju CHEN, Nanjing City (CN); Min-Yao CHEN, Nanjing City (CN); Jiun-Hua CHIUE, Nanjing City (CN); Andrew C. CHANG, Nanjing City (CN); Chung-Hsien YANG, Nanjing City (CN); Chen-Yin FAN, Nanjing City (CN)

(73) Assignee: AaltoSemi Inc., Nanjing City (CN)

(21) Appl. No.: 19/180,543

(22) Filed: Apr. 16, 2025

(30) Foreign Application Priority Data
May 30, 2024 (CN) 202410691921.0

(51) Int. Cl. H01L 21/48

(52) U.S. Cl. CPC H01L 21/486

(57) ABSTRACT

Provided is a method for fabricating a package substrate including forming a heterogeneous layer on a board body; forming a first circuit layer on the heterogeneous layer; and forming a dielectric layer on the heterogeneous layer, such that the first circuit layer is embedded in the dielectric layer. After that, build-up circuit layers are provided, and the board body and the heterogeneous layer are removed, making the depth of the first circuit layer consistent to facilitate the bonding of a plurality of solder balls to the first circuit layer.

### CROSS-REFERENCE TO RELATED APPLICATIONS

This application claims priority to Chinese Patent Application No. 202410691921.0, filed on May 30, 2024, the entire contents of which are incorporated herein by reference and made a part of this specification.

### BACKGROUND

### 1. Technical Field

The present disclosure relates to a semiconductor packaging process, and more particularly, to a method of fabricating a package substrate that enhances reliability.

### 2. Description of Related Art

With the booming development of the electronics industry, electronic products tend to be thin, light and small in form, and the functionality is developing towards the direction of high-performance, high-function and high-speed research and development. Therefore, in order to meet the demand for high integration and miniaturization of semiconductor devices, package substrates having high-density and fine-pitch circuits are often used in the packaging process.

FIG. 1A to FIG. 1F are schematic cross-sectional views showing a conventional fabricating method of a package substrate 1 according to the prior art.

As shown in FIG. 1A, a carrier 9 is provided. A separation layer 91 is formed on a surface of a board body 90 of the carrier 9, and a metal layer 92 is formed on the separation layer 91. Subsequently, a resist layer 10 having openings 100 is symmetrically formed on each of the opposite sides of the carrier 9, such that part of the surfaces of the carrier 9 is exposed from the openings 100.

As shown in FIG. 1B, a first circuit layer 11 is formed on the metal layer 92 in the openings 100, and the resist layer 10 is subsequently removed.

As shown in FIG. 1C, a dielectric layer 12 is formed on the metal layer 92 of the carrier 9, and a plurality blind vias 120 are formed in the dielectric layer 12.

As shown in FIG. 1D, copper is electroplated on the dielectric layer 12 and in the blind vias 120 to form a second circuit layer 13 on the dielectric layer 12, and a plurality of conductive pillars 14 electrically connecting the first circuit layer 11 and the second circuit layers 13 are formed in the blind vias 120 to form a coreless circuit structure 1a.

As shown in FIG. 1E, the board body 90 of the carrier 9 is separated from the circuit structure 1a by the separation layer 91 to retain the metal layer 92 on the dielectric layer 12 and the first circuit layer 11.

As shown in FIG. 1F, the metal layer 92 is removed by etching, and part of the material of the first circuit layer 11 is removed by micro-etching at the same time to form a plurality of grooves 15 in the dielectric layer 12.

In addition, in a subsequent process, as shown in FIG. 1G, solder balls 16 are electrically bonded to the first circuit layer 11 in the grooves 15 to enable the package substrate 1 to be connected to a semiconductor wafer (not shown) or an electronic device, such as a circuit board (not shown), by means of the solder balls 16.

However, in the prior art package substrate 1, the first circuit layer 11, 11a is micro-etched when the metal layer 92 is removed by etching, resulting in inconsistencies in the depths D1, D2, D3, D4, D5, D6 of the grooves 15, thereby making it difficult to efficiently bond them to all the solder balls 16. Accordingly, the reliability of the package substrate 1 is not good. For example, the depth D2 of the groove 15 is too shallow, making it difficult for the solder ball 16 to be embedded in the groove 15, thereby causing the solder ball 16 to fall out. Alternatively, the depth D5 of the groove 15 is too deep, making it difficult for the solder ball 16 to protrude from the groove 15, resulting in the solder ball 16 being unable to be soldered to a contact of an external electronic device.

Moreover, since the first circuit layer 11, 11a is micro-etched when the metal layer 92 is removed by etching, part of the first circuit layer 11a may be lateral-etched, resulting in damage or even breakage of the first circuit layer 11a, thereby causing poor signal transmission between the first circuit layer 11a and the solder balls 16.

Further, since the first circuit layer 11a is subject to damage due to lateral etching, when the line width/line spacing (L/S) of the first circuit layer 11 is designed to be miniaturized, the first circuit layer 11a is more likely to break, resulting in a signal transmission breakage between the first circuit layer 11a and the solder balls 16, and thus making it impossible to mass-fabricate the package substrate 1 on which the first circuit layer 11, 11a needs to be miniaturized.

Therefore, how to overcome the various problems of the above-mentioned prior art technology has become an urgent issue to be solved.

### SUMMARY

In view of the various shortcomings of the aforementioned prior art technologies, the present disclosure provides an improved package substrate. The package substrate comprises: a dielectric layer having a first surface and a second surface opposing the first surface; a first circuit layer embedded in the first surface of the dielectric layer, wherein first circuit layer is flush with the first surface of the dielectric layer; a second circuit layer formed on the second surface of the dielectric layer; and a plurality of conductive pillars formed in the dielectric layer and electrically connecting the first circuit layer and the second circuit layer.

The present disclosure further provides a method of fabricating a package substrate. The method comprises: providing a board body having a heterogeneous layer thereon; forming a first circuit layer on the heterogeneous layer; forming a dielectric layer on the heterogeneous layer and the first circuit layer, wherein the dielectric layer has a first surface and a second surface opposing the first surface, and the dielectric layer is bonded to the heterogeneous layer by the first surface thereof; forming a second circuit layer on the second surface of the dielectric layer, and forming a plurality of conductive pillars in the dielectric layer that electrically connect the first circuit layer and the second circuit layer; and separating the board body from the heterogeneous layer, and removing the heterogeneous layer by etching to expose the first circuit layer, making the first circuit layer flush with the first surface of the dielectric layer.

In the aforementioned fabricating method, a material of forming the first circuit layer is different from a material of forming the heterogeneous layer.

In the aforementioned fabricating method, a separation layer is formed on the board body, and then the heterogeneous layer is formed on the separation layer. For example, a material for forming the separation layer is different from a material for forming the heterogeneous layer. In an exemplary embodiment, the separation layer is a copper layer.

In an exemplary embodiment of the aforementioned fabricating method, the heterogeneous layer is a nickel layer or an aluminum layer.

In an exemplary embodiment of the aforementioned fabricating method, the second circuit layer is formed integrally with the plurality of conductive pillars.

As can be seen from the above, in the package substrate and fabricating method thereof of the present disclosure, by means of the configuration of the heterogeneous layer, the first circuit layer will not be micro-etched when removing the metal layer, and thus the thickness of the first circuit layer can be effectively controlled, such that the thickness of the first circuit layer is consistent. Accordingly, compared to the conventional technology, in the subsequent process of the present disclosure, the plurality of solder balls can be effectively bonded to the first circuit layer, thereby avoiding the problem of the solder balls falling off or not being soldered and enhancing the reliability.

Moreover, by the configuration of the heterogeneous layer, the removal of the heterogeneous layer does not remove part of the material of the first circuit layer, thereby effectively preventing the occurrence of lateral etching of the first circuit layer. Hence, compared to the conventional technology, the present disclosure can avoid the problem of damage (e.g., breakage) of the first circuit layer to improve the yield of signal transmission between the first circuit layer and the solder balls.

Further, when the line width/line spacing (L/S) of the first circuit layer is designed towards miniaturization, the first circuit layer will not be damaged (e.g., broken) due to lateral etching, and the signal transmission between the first circuit layer and the solder balls can be effectively ensured. Therefore, compared to the conventional technology, the present disclosure is advantageous for mass production of package substrates that require the deployment of a miniaturized first circuit layer.

In addition, the fabricating method of the present disclosure is applicable to any fine line specification process, and no matter how thin the carrier is, by coating a thin heterogeneous layer, a groove-free structure can be realized, thereby increasing the signal transmission speed between the solder balls and the first circuit layer and improving the packaging yield.

### BRIEF DESCRIPTION OF THE DRAWINGS

FIG. 1A to FIG. 1F are schematic cross-sectional views showing a prior art fabricating method of a package substrate.

FIG. 1G is a schematic cross-sectional view showing the subsequent process of FIG. 1F.

FIG. 2A-1 and FIG. 2B to FIG. 2F are schematic cross-sectional views showing an exemplary fabricating method of a package substrate according to the present disclosure.

FIG. 2A-2 is a schematic cross-sectional view showing another exemplary process of FIG. 2A-1.

### DETAILED DESCRIPTION

The following describes the implementation of the present disclosure with examples. Those skilled in the art can easily understand other advantages and effects of the present disclosure from the content disclosed in this specification.

It should be noted that the structures, proportions, sizes, etc. depicted in the drawings appended to this specification are used in coordination with the content disclosed in the specification to facilitate understanding for those skilled in the art. They are not intended to limit specific conditions of implementing the techniques and methods of this disclosure. Any modification of the structures, alteration of the ratio relationships, or adjustment of the sizes of the structures and techniques disclosed herein that do not affect their possible effects and achievable proposes should be deemed as falling within the scope defined by the technical content disclosed in the present specification. Meanwhile, terms such as “on,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure.

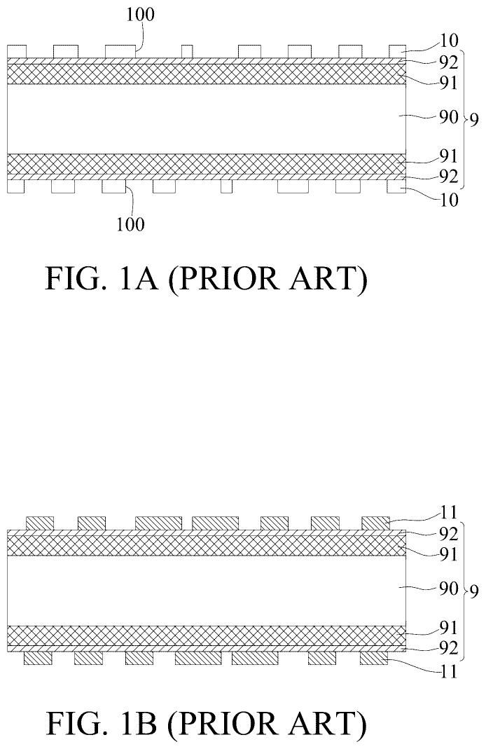

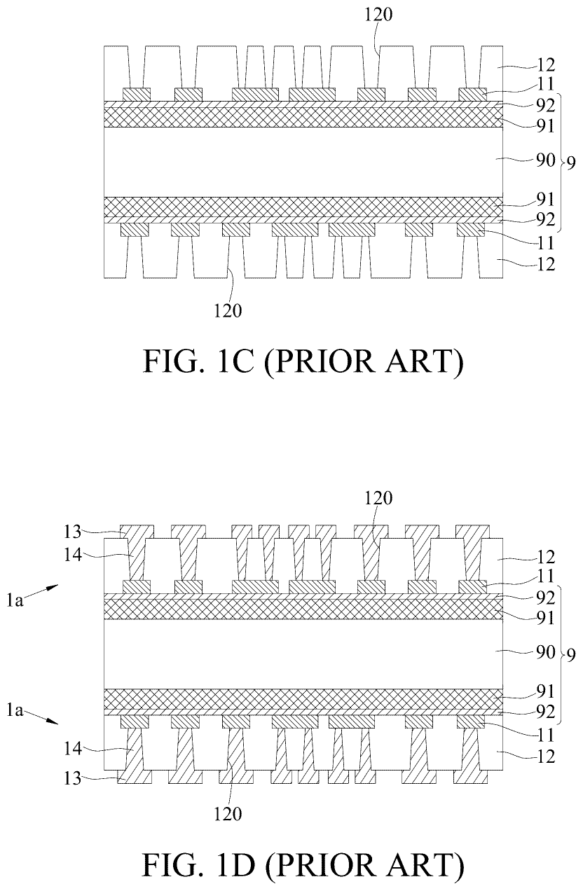

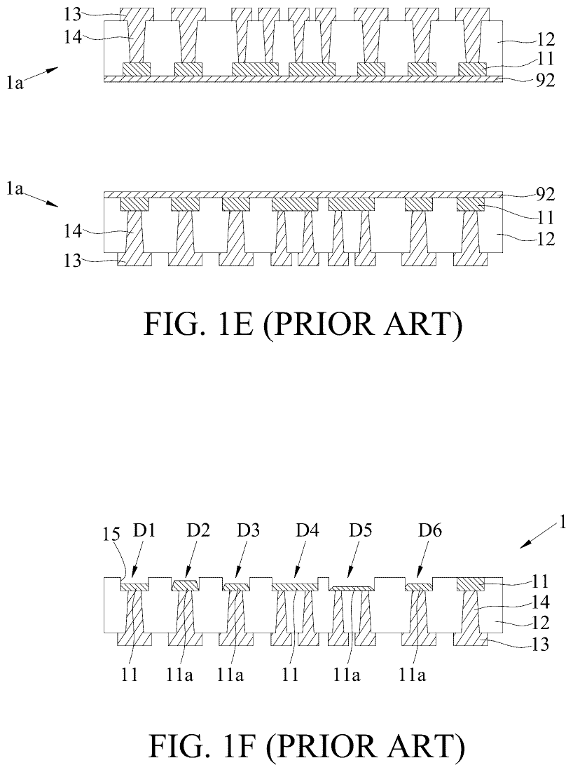

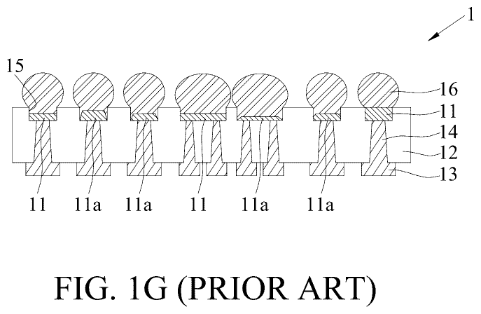

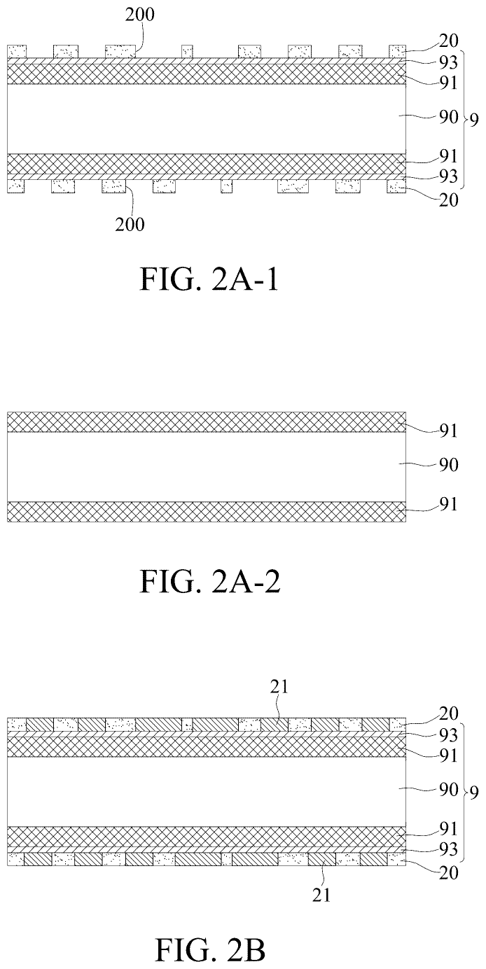

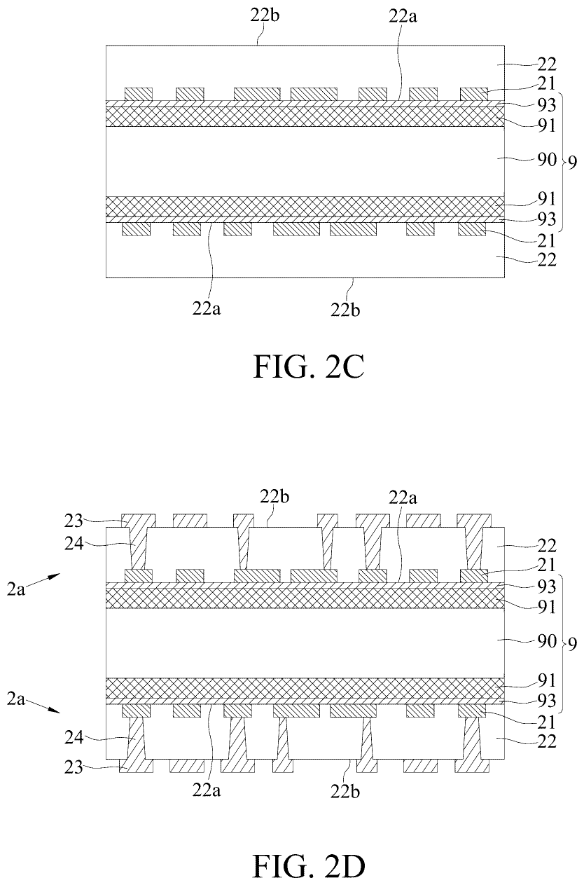

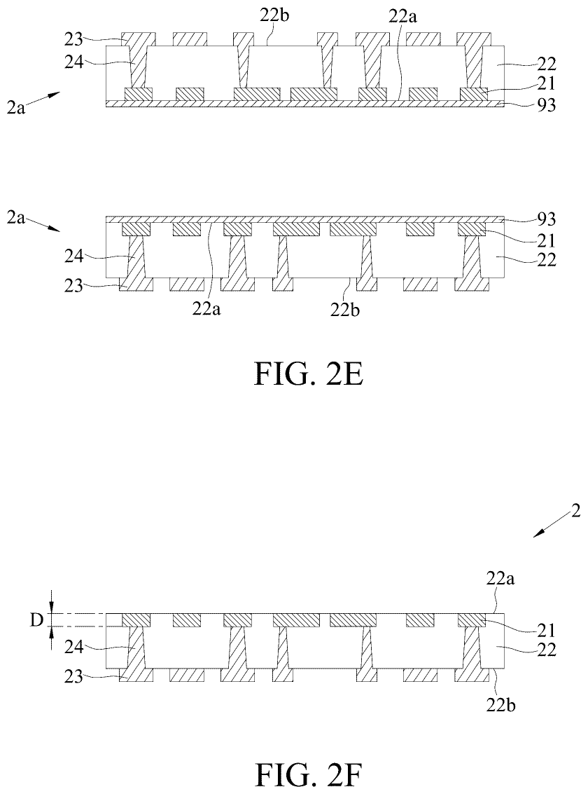

FIG. 2A-1 and FIG. 2B to FIG. 2G are schematic cross-sectional views showing an exemplary fabricating method of a package substrate 2 according to the present disclosure.

As shown in FIG. 2A-1, a carrier 9 is provided. A resist layer 20 having openings 200 is formed symmetrically on each of opposite sides of the carrier 9, such that portions of the surfaces of the carrier 9 are exposed from the openings 200.

In an exemplary embodiment, the carrier 9 is a temporary carrier board, which may be a board having a metal layer on both opposite sides, and the surface of the board body 90 has separation layer 91 made of metal material, and a heterogeneous layer 93 is formed on the separation layer 91.

Moreover, the resist layer 20 is a dry film, the separation layer 91 is a metal material containing copper, such as a copper layer, and the heterogeneous layer 93 is a metal material containing non-copper material, such as, for example, a nickel layer or an aluminum layer, and so on. Accordingly, the separation layer 91 and the heterogeneous layer 93 are metal layers made of different materials from each other. For example, a board body 90 having a separation layer 91, such as the copper foil substrate shown in FIG. 2A-2, can be provided first, and the heterogeneous layer 93 is subsequently formed on the separation layer 91 by sputtering, E-less coating, or other means.

As shown in FIG. 2B, a patterned wiring process is performed to form a first circuit layer 21 on the heterogeneous layer 93.

In an exemplary embodiment, the first circuit layer 21 is copper, such that the material of forming the first circuit layer 21 is different from the material of forming the heterogeneous layer 93. For example, the first circuit layer 21 adopts a circuit redistribution layer (RDL) specification.

As shown in FIG. 2C, the resist layer 20 is removed, and a dielectric layer 22 is subsequently formed on the heterogeneous layer 93 of the carrier 9. The dielectric layer 22 has a first surface 22a and a second surface 22b opposing the first surface 22a, such that the dielectric layer 22 is bonded to the heterogeneous layer 93 by the first surface 22a thereof.

In an embodiment, the dielectric layer 22 is a dielectric material, such as ajinomoto build-up film (ABF), polybenzoxazole (PBO), polyimide (PI), prepreg (PP) with glass fibers, or other dielectric materials.

As shown in FIG. 2D, a second circuit layer 23 is formed on the second surface 22b of the dielectric layer 22, and a plurality of conductive pillars 24 electrically connecting the first circuit layer 21 and the second circuit layer 23 are formed in the dielectric layer 22 to form a coreless circuit structure 2a.

In an exemplary embodiment, the second circuit layer 23 is fabricated by electroplating metal (e.g., copper) or other means using a build-up process. For example, the second circuit layer 23 and the conductive pillars 24 are formed integrally by first forming a plurality of blind vias on the second surface 22b of the dielectric layer 22 by means of laser, and subsequently electroplating copper on the dielectric layer 22 and in the blind vias.

Further, the second circuit layer 23 is copper. For example, the second circuit layer 23 adopts a circuit redistribution layer (RDL) specification.

It should be appreciated that by utilizing the build-up process, the number of layers of the dielectric layer can be designed according to the demand, so as to fabricate the desired number of layers the second circuit layer 23 in the circuit structure 2a.

As shown in FIG. 2E, the heterogeneous layer 93 is retained on the first surface 22a of the dielectric layer 22 by separating the board body 90 of the carrier 9 from the circuit structure 2a by the separation layer 91.

In an embodiment, the separation layer 91 is removed by etching or other means, for example, by etching copper with an etchant such as Ferric chloride etchant, hydrochloric acid with oxidant, ammonia water, or sulfuric acid with oxidant, and so on.

As shown in FIG. 2F, the heterogeneous layer 93 is removed by etching, such that the first circuit layer 21 is embedded in the dielectric layer 22 and exposed to the first surface 22a of the dielectric layer 22, and the first circuit layer 21 is flush with the first surface 22a of the dielectric layer 22.

In an embodiment, an etchant used to etch the heterogeneous layer 93 (Ni material) includes free hydrogen, nitrate, phosphate radical and/or metal ions. Accordingly, when etching the heterogeneous layer 93, the first circuit layer 21 is not etched. The selection of etchant depends on the material used in the heterogeneous layer 93 but is not limited thereto.

In addition, in the subsequent process, solder balls (not shown) may be bonded to and electrically connected to the first circuit layer 21, such that the package substrate 2 can be connected to electronic devices such as semiconductor wafers, passive components, silicon intermediary boards, circuit boards, or other components by means of the solder balls in order to form an electronic package.

Therefore, in the fabricating method of the present disclosure, the heterogeneous layer 93 made of a material different from that of the first circuit layer 21 is formed, such that the first circuit layer 21 will not be micro-etched when the heterogeneous layer 93 is removed. Therefore, after removing the heterogeneous layer 93, the first circuit layer 21 is flush with the first surface 22a of the dielectric layer 22, and no groove is formed on the first surface 22a of the dielectric layer 22, thereby effectively controlling the thickness D of the first circuit layer 21 to be consistent, resulting in the plurality of solder balls to be effectively bonded to the first circuit layer 21, and thus avoiding the problem of the solder balls falling off or not soldering the electronic devices.

Moreover, since the material used to form the first circuit layer 21 is different from the material used to form the heterogeneous layer 93, when the heterogeneous layer 93 is removed, part of the material of the first circuit layer 21 will not be removed, so as to effectively prevent the occurrence of lateral etching of the first circuit layer 21, and thus avoid the problem of damage (e.g., breakage), thereby avoiding the problem of poor signal transmission between the first circuit layer 21 and the solder balls.

Also, when the line width/line spacing (L/S) of the first circuit layer 21 is designed towards miniaturization, the first line layer 21 is not subject to damage (e.g., breakage) due to lateral etching, so as to ensure that the signal transmission between the first circuit layer 21 and the solder balls is normal. Hence, the fabricating method of the present disclosure is advantageous for mass production of the package substrate 2 which needs to be equipped with the miniaturized first circuit layer 21 by the design of the heterogeneous layer 93.

In addition, the fabricating method of the present disclosure is applicable to any fine line specification process, and no matter how thin the board body 90 or the copper foil substrate is, by coating a thinner heterogeneous layer 93, a groove-free structure can be realized, thereby increasing the signal transmission speed between the solder balls and the first circuit layer 21 and improving the packaging yield.

The present disclosure also provides a package substrate 2. The package substrate 2 includes at least one dielectric layer 22, a first circuit layer 21, at least one second circuit layer 23 and a plurality of conductive pillars 24.

The dielectric layer 22 has a first surface 22a and a second surface 22b opposing the first surface 22b.

The first circuit layer 21 is embedded in the first surface 22a of the dielectric layer 22, and the first circuit layer 21 is flush with the first surface 22a of the dielectric layer 22.

The second circuit layer 23 is formed on the second surface 22b of the dielectric layer 22.

The conductive pillars 24 are formed in the dielectric layer 22 and electrically connect the first circuit layer 21 and the second circuit layer 23.

In an embodiment, the second circuit layer 23 is formed integrally with the plurality of conductive pillars 24.

In summary, in the package substrate and fabricating method thereof of the present disclosure, by means of the configuration of the heterogeneous layer, the thickness of the first circuit layer is effectively controlled to be consistent, such that the plurality of solder balls can be effectively bonded to the first circuit layer. Hence, the problem of the solder balls falling off or not being soldered is avoided, and thus the present disclosure can enhance the reliability.

Further, by configuring the heterogeneous layer, the removal of the heterogeneous layer does not remove part of the material of the first circuit layer, thereby effectively preventing the occurrence of lateral etching of the first circuit layer. Hence, the present disclosure is able to avoid the problem of damage (e.g., breakage) of the first circuit layer to improve the yield of signal transmission between the first circuit layer and the solder balls.

Also, when the line width/line spacing (L/S) of the first circuit layer is designed towards miniaturization, the first circuit layer will not be damaged (e.g., broken) due to lateral etching, and the signal transmission between the first circuit layer and the solder balls can be effectively ensured. Therefore, the present disclosure is advantageous for mass production of package substrates that require the deployment of a miniaturized first circuit layer.

In addition, the fabricating method of the present disclosure is applicable to any fine line specification process, and no matter how thin the carrier is, by coating a thin heterogeneous layer, a groove-free structure can be realized, thereby increasing the signal transmission speed between the solder balls and the first line layer and improving the packaging yield.

The above embodiments are provided for illustrating the principles of the present disclosure and its technical effect and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A method of fabricating a package substrate, the method comprising:
providing a board body having a heterogeneous layer thereon;
forming a first circuit layer on the heterogeneous layer;
forming a dielectric layer on the heterogeneous layer and the first circuit layer, wherein the dielectric layer has a first surface and a second surface opposing the first surface, and the dielectric layer is bonded to the heterogeneous layer by the first surface thereof;
forming a second circuit layer on the second surface of the dielectric layer, and forming a plurality of conductive pillars in the dielectric layer that electrically connect the first circuit layer and the second circuit layer; and
separating the board body from the heterogeneous layer, and removing the heterogeneous layer by etching to expose the first circuit layer, making the first circuit layer flush with the first surface of the dielectric layer.

2. The method of claim 1, wherein a material of forming the first circuit layer is different from a material of forming the heterogeneous layer.

3. The method of claim 1, further comprising forming a separation layer on the board body, and then forming the heterogeneous layer on the separation layer.

4. The method of claim 3, wherein a material of forming the separation layer is different from a material of forming the heterogeneous layer.

5. The method of claim 3, wherein the separation layer is a copper layer.

6. The method of claim 1, wherein the second circuit layer is formed integrally with the plurality of conductive pillars.

7. The method of claim 1, wherein the heterogeneous layer is a nickel layer or an aluminum layer.
